(19) United States
(12) Patent Application Publication
(10) Pub. No.: US 2007/0176629 A1
(43) Pub. Date: Aug. 2, 2007

(54) Molecular electronic device having organic conducting electrode as protective layer

(75) Inventors: Hyoyoung Lee, Daejeon-city (KR); Nak Jin Choi, Daegu-city (KR); Jung Hyun Lee, Gyeonggi-do (KR); Jong Hyurk Park, Daegu-city (KR); Gyeong Sook Bang, Jeollabuk-do (KR); Hee Yeol Baek, Gyeongsangbuk-do (KR)

Correspondence Address: MAYER, BROWN, ROWE & MAW LLP, 1909 K STREET, N.W., WASHINGTON, DC, 20006, US

(73) Assignee: ELECTRONICS AND TELECOMMUNICATIONS RESEARCH INSTITUTE

(21) Appl. No.: 11/589,812

(22) Filed: Oct. 31, 2006

(30) Foreign Application Priority Data
Nov. 28, 2005 (KR) 10-2005-0114198
Feb. 27, 2006 (KR) 10-2006-0018872

(51) Int. Cl. H03K 19/173

(52) U.S. Cl. 326/37

(57) ABSTRACT

Provide is a molecular electronic device which includes a first electrode, a molecular active layer self-assembled on the first electrode using a thiol-based anchoring group or a silane-based anchoring group, and a second electrode including an organic electrode layer covering the molecular active layer. The organic electrode layer includes a highly conductive monomer, an oligomer or a polymer. The molecular active layer composes a switching element which is mutually switchable to states of ON and OFF according to voltages applied between the first electrode and the second electrode, and a memory element in which a predetermined electric signal is stored according to voltages applied between the first electrode and the second electrode.

### CROSS-REFERENCE TO RELATED PATENT APPLICATION

This application claims the benefit of Korean Patent Application No. 10-2005-0114198, filed on Nov. 28, 2005 and No. 10-2006-0018872, filed on Feb. 27, 2006 in the Korean Intellectual Property Office, the disclosures of which are incorporated herein in its entirety by reference.

### BACKGROUND OF THE INVENTION

1. Field of the Invention

The present invention relates to a molecular electronic device, and more particularly, to a molecular electronic device including two electrodes between which a molecular active layer having electric properties, is interposed.

2. Description of the Related Art

It has been recently discovered that organic materials having π-electrons that form conjugate bonds have semiconductor properties, and thus considerable research is being conducted to develop such organic semiconductor materials. Most of this research concerns the electric transfer properties of organic layers interposed between two metal electrodes. Also, vigorous research is being conducted to apply such materials to molecular switch/memory devices using a charging phenomenon that occurs due to the polarization of π-electrons in the molecules. In particular, as research for developing electric devices has been extensively conducted in order to commercialize nano semiconductors on the scale of several tens of namometers, development of more integrated and more fine molecular electric devices are required.

Molecular electronic devices, which are known to those of ordinary skill in the art, include two metal electrodes and an organic molecular active layer interposed between the two metal electrodes. The organic molecular active layer provides organic semiconductor properties between the two electrodes. Recently, a method of forming a molecular active layer on a metal electrode to be a single molecular layer using self-assembling method, has been performed.

According to this method, a molecular active layer is formed to be a single molecular layer of several nanometers in thickness, and thus the molecular active layer is damaged when a metal for forming electrodes is deposited on the molecular active layer. In particular, when Ti or Au is deposited as the metal for forming electrodes, electrode materials, i.e. Ti or Au, is penetrated into the molecular active layer to cause a short circuit in the molecular electronic device. Therefore, the commercialization of molecular electronic devices is difficult.

### SUMMARY OF THE INVENTION

The present invention provides a molecular electronic device in which desired electric properties are provided effectively by inhibiting a short circuit caused by damage to a molecular active layer formed to be a single molecular film using self-assembling methods when ultra integrated nano-electric devices, having structures of several nanometers through several tens of nanometers, are implemented.

According to an aspect of the present invention, there is provided a molecular electronic device including: a first electrode; a molecular active layer self-assembled on the first electrode; and a second electrode including an organic electrode layer covering the molecular active layer.

According to another aspect of the present invention, there is provided the molecular electronic device, wherein the second electrode further includes a metal electrode layer formed on the organic electrode layer.

According to another aspect of the present invention, there is provided the molecular electronic device, wherein the molecular active layer comprises a compound including a thiol derivative or a silane derivative, and self-assembled to the first electrode by the thiol derivative or the silane derivative constituting an anchoring group.

According to another aspect of the present invention, there is provided the molecular electronic device, wherein the molecular active layer is formed to be a single molecular layer.

According to another aspect of the present invention, there is provided the molecular electronic device, wherein the molecular active layer comprises at least one selected from the group consisting of a compound including a nitro phenylene ethynylenethiol group, a compound including a nitro phenylene ethynylene silane group, a compound including a rose bengal thiol group, a compound including a rose bengal silane group, an azo compound comprising a aminobenzene group including a dinitro thiophene group and a thiol derivative, an azo compound comprising a aminobenzene group including a dinitro thiophene group and a silane derivative, an organic metal-thiol derivative including a terpyridyl group and a metal atom bonded on the organic metal-thiol derivative, and the organic metal-silane derivative including a terpyridyl group and a metal atom bonded on the organic metal-silane derivative.

According to another aspect of the present invention, there is provided the molecular electronic device, wherein the metal atom is any one selected from the group consisting of cobalt, nickel, iron and ruthenium.

According to another aspect of the present invention, there is provided the molecular electronic device, wherein the organic electrode layer includes at least one selected from the group consisting of tetrathiafulvalene-tetracyanoquinodimethane (TTF-TCNQ), bis(ethylenedithio)tetrathiafulvalene (BEDT-TTF), oligo thiophene, pentacene, perylene, polyacetylene, polyaniline emeraldine salt (PANI-ES), polypyrrole (PPy), polyphenylvinyl (PPV), polyparaphenylene (PPP), poly(vinylpyrrolidone), poly(alkylthiophene), and poly(thienylenevinylene).

According to another aspect of the present invention, there is provided the molecular electronic device, wherein the first electrode comprises a single metal layer formed of one metal, or a multi-layer structure comprising at least two sequentially stacked metals which are different from each other.

According to another aspect of the present invention, there is provided the molecular electronic device, wherein the metal electrode layer of the second electrode comprises a single metal layer formed of one metal, or a multi-layer structure comprising at least two sequentially stacked metals which are different from each other.

According to another aspect of the present invention, there is provided the molecular electronic device, wherein the first electrode and the second electrode each include a metal layer including Au, Pt, Ag or Cr.

According to another aspect of the present invention, there is provided the molecular electronic device, wherein a metal electrode of the second electrode has a stack structure of a barrier layer and a metal layer, and the barrier layer is formed directly on the organic electrode layer.

According to another aspect of the present invention, there is provided the molecular electronic device, wherein the barrier layer includes Ti, and the metal layer includes Au.

According to another aspect of the present invention, there is provided the molecular electronic device, wherein the molecular active layer composes a switching element which is mutually switchable to states of ON and OFF according to voltages applied between the first electrode and the second electrode.

According to another aspect of the present invention, there is provided the molecular electronic device, wherein the molecular active layer composes a memory element in which a predetermined electric signal is stored according to voltages applied between the first electrode and the second electrode.

According to the present invention, to inhibit a short circuit by damage of the molecular active layer which is formed to be a single molecular layer self-assembled on the metal electrode, the organic electrode layer is formed for protecting the molecular active layer as an element of the upper electrode. Thus, a short circuit caused by damage of the molecular active layer can be inhibited and the ultra slim nano sized molecular electronic device having a fine structure of several nanometer scale can be implemented.

### BRIEF DESCRIPTION OF THE DRAWINGS

The above and other features and advantages of the present invention will become more apparent by describing in detail exemplary embodiments thereof with reference to the attached drawings in which:

FIG. 1A is a layout illustrating a structure of a molecular electronic device according to an embodiment of the present invention;

FIG. 1B is a cross-sectional view of the molecular electronic device taken along a line Ib-Ib′ in FIG. 1A, according to an embodiment of the present invention;

FIG. 2A is a layout illustrating a structure of a molecular electronic device according to another embodiment of the present invention;

FIG. 2B is a cross-sectional view of the molecular electronic device taken along a line IIb-IIb′ of FIG. 2A, according to an embodiment of the present invention.

FIG. 3 is a cross-sectional view illustrating a structure of a molecular electronic device according to another embodiment of the present invention.

FIG. 4 is a hysteresis graph illustrating switching characteristics of a molecular electronic device according to an embodiment of the present invention.

FIG. 5 is a graph illustrating memory characteristics of a molecular electronic device according to an embodiment of the present invention.

### DETAILED DESCRIPTION OF THE INVENTION

The present invention will now be described more fully with reference to the accompanying drawings, in which exemplary embodiments of the invention are shown. The invention may, however, be embodied in many different forms and should not be construed as being limited to the embodiments set forth herein; rather, these embodiments are provided so that this disclosure will be thorough and complete, and will fully convey the concept of the invention to those skilled in the art. In the drawings, the thickness of layers and regions are exaggerated for clarity. Like reference numerals in the drawings denote like elements, and thus their description will be omitted.

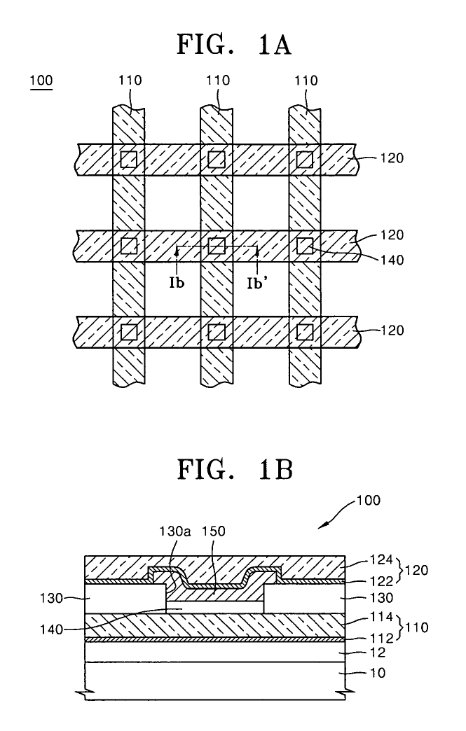

FIG. 1A is a layout illustrating a structure of a molecular electronic device 100 according to an embodiment of the present invention. Referring to FIG. 1A, the molecular electronic device 100 includes a plurality of lower electrodes 110 as first electrodes and a plurality of upper metal electrodes 120 as second electrodes, which are arranged in 3×3 arrays. FIG. 1B is a cross-sectional view of the molecular electronic device 100 taken along a line Ib-Ib′ in FIG. 1A. Referring to FIGS. 1A and 1B, the molecular electronic device 100 according to the current embodiment of the present invention includes an insulating layer 12 formed on a substrate 10. One of the lower electrodes 110, that is one of the first electrodes, and one of the upper metal electrodes 120 included in one of the second electrodes are formed on the insulating layer 12, and extend in perpendicular directions to each other so as to intersect each other at respective predetermined positions. The substrate 10 may be a silicon substrate, and the insulating layer 12 may be a silicon oxide film, a silicon nitride film, or a combination thereof.

The lower electrode 110 may include, for example, a metal or doped polysilicon. According to the current embodiment of the present invention, as illustrated in FIG. 1B, the lower electrode 110 may include a first barrier layer 112 and a first metal layer 114. The upper metal electrode 120 may include a second barrier layer 122 and a second metal layer 124. The first barrier layer 112 and the second barrier layer 122 are each formed to inhibit a metal atom, for example, an Au atom deposited on the first barrier layer 112 and the second barrier layer 122 from being penetrated into the structures thereunder. The first barrier layer 112 and the second barrier layer 122 may be formed of Ti. The first barrier layer 112 and the second barrier layer 122 may be each omitted on occasion. The first metal layer 114 and the second metal layer 124 may be each formed of Au, Pt, Ag or Cr.

An insulating layer pattern 130 is interposed between the lower electrode 110 and the upper metal electrode 120. The insulating layer pattern 130 may be formed of a silicon nitride film, a silicon oxide film, or combinations thereof. In the insulating layer pattern 130, a nano via hole 130a having a diameter of about 100-160 nm is formed at a position where the lower electrode 110 and the upper metal electrode 120 intersect.

A molecular active layer 140 is formed on the surface of the lower electrode 110 exposed through the nano via hole 130a. The molecular active layer 140 may be a single molecular layer self-assembled on the surface of the lower electrode 110. Examples of materials used to form the molecular active layer 140 will be described later.

An organic conductive protective layer 150 for protecting the molecular active layer 140 is formed between the molecular active layer 140 and the upper metal electrode 120. The organic conductive protective layer 150 is formed in order to inhibit the materials of the upper metal electrode 120 from being penetrated into the molecular active layer 140 which is beneath the upper metal electrode 120 or in order to prevent the molecular active layer 140 from being damaged when the materials of the upper metal electrode 120 are deposited. The organic conductive protective layer 150 and the upper metal electrode 120 are included in an upper electrode constituting the second electrode of the molecular electronic device 100 according to the current embodiment of the present invention.

The organic conductive protective layer 150 should be thick enough to prevent short circuits due to damage of the molecular active layer 140 in the molecular electronic device 100. The thickness of the organic conductive protective layer 150 may be determined according to the sizes and thicknesses of the molecular active layer 140 and the insulating layer pattern 130, and the sizes and thicknesses of respective elements neighboring thereof. In order to form a fine molecular electronic device on a scale of several tens of nanometers which can meet recent demands, for example, the organic conductive protective layer 150 may have a thickness of about 1-50 nm. Examples of materials suitable for the organic conductive protective layer 150 will be described later.

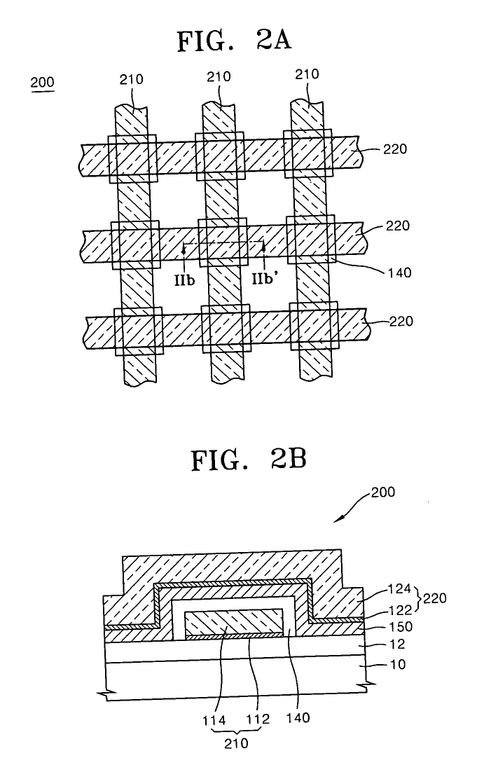

FIG. 2A is a layout of structure of a molecular electronic device 200 according to another embodiment of the present invention. Referring to FIG. 2A, the molecular electronic device 200 includes a plurality of lower electrodes 210 and a plurality of upper metal electrodes 220 arranged in 3×3 arrays. FIG. 2B is a cross-sectional view taken along a line IIb-IIb′ in FIG. 2A, according to an embodiment of the present invention. In FIGS. 2A and 2 B, like reference numerals in FIGS. 1A and 1B denote like elements.

Referring to FIGS. 2A and 2B, the molecular electronic device 200 according to the current embodiment of the present invention includes an insulating layer 12 on a substrate 10. The lower electrodes 210, as first electrodes, and the upper metal electrodes 220 as second electrodes are formed on the insulating electrode 12, and extend in perpendicular directions to each other so as to intersect each other at respective predetermined positions.

The lower electrodes 210 and the upper metal electrodes 220 illustrated in FIGS. 2A and 2B are equivalent to the lower electrodes 110 and the upper metal electrodes 120 of FIGS. 1A and 1B, and thus detailed descriptions thereof will be omitted.

A molecular active layer 140 is formed on the surface of each of the lower electrodes 210. The molecular active layer 140 may be a single molecular layer which is self-assembled on the surface of each of the lower electrodes 210. An organic conductive protective layer 150 for protecting the molecular active layer 140 is formed between the molecular active layer 140 and each of the upper metal electrodes 220. The organic conductive protective layer 150 and the upper metal electrodes 220 are included in upper electrodes constituting the second electrodes of the molecular electronic device 200 according to the current embodiment of the present invention.

The molecular active layer 140 and the organic conductive protective layer 150 illustrated in FIGS. 2A and 2B are equivalent to the molecular active layer 140 and the organic conductive protective layer 150 illustrated in FIGS. 2A and 2B, and thus detailed descriptions thereof will be omitted.

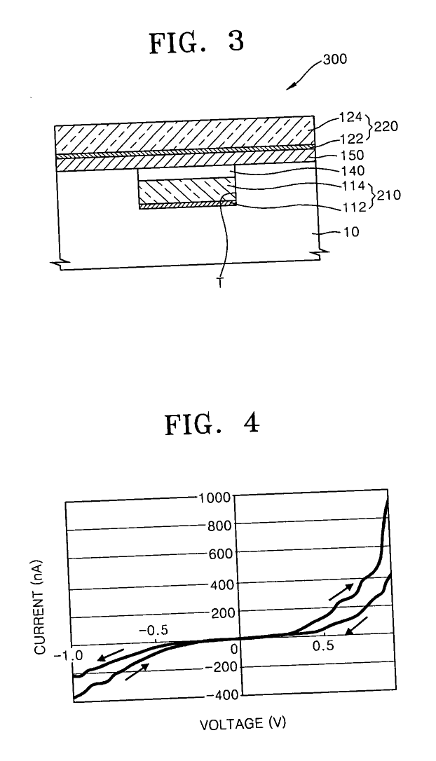

FIG. 3 is a cross-sectional view illustrating a structure of a molecular electronic device 300 having a trench structure according to another embodiment of the present invention. A top view of the structure corresponding to FIG. 3 may correspond to the layouts of FIG. 1A or 2A. FIG. 3 is a cross-sectional view corresponding to the cross-sectional view taken along the line IIb-IIb′ in FIG. 2A. In FIG. 3, like reference numerals in FIGS. 1A, 1B, 2A and 2B denote like elements.

Referring to FIG. 3, the molecular electronic device 300 according to the current embodiment of the present invention is formed on a substrate 10. A lower electrode 210 as a first electrode is formed in a trench (T) formed in the substrate 10. An insulating layer (not shown) is interposed between the substrate 10 and the lower electrode 210.

A molecular active layer 140 is formed on the surface of the lower electrode 210. An organic conductive protective layer 150 for protecting the molecular active layer 140 is formed between the molecular active layer 140 and an upper metal electrode 220 included in a second electrode. The organic conductive protective layer 150 and the upper metal electrode 220 are included in an upper electrode constituting the second electrode of the molecular electronic device 300 according to the current embodiment of the present invention. The molecular active layers 140 included in the molecular electronic devices 100, 200 and 300 according to embodiments of the present invention may include compounds having rectification characteristics or hysteresis characteristics such as compounds including electron donors—electron acceptor thiol group or silane group. For example, the molecular active layer 140 may be selected from the group consisting of compounds including a nitrophenylene ethinylene thiol group or silane group; compounds including a rose bengal thiol group or silane group; azo compounds including an aminobenzene group having a dinitro thiophene group, and a thiol derivative or a silane derivative; and an organic metal-thiol derivative or a silane derivative in which a terpyridyl group and a metal atom (for example, cobalt, nickel, iron and ruthenium) are bonded.

Formulas (1) and (2) are compounds of a nitro phenylene ethynylene thiol group or silane group.

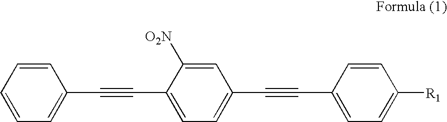

In Formula (1), R₁ is SH, SiCl₃ or Si(OCH₃)₃.

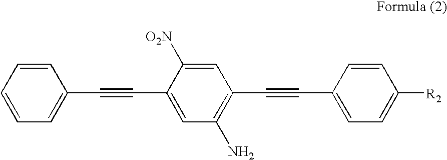

In Formula (2), R₂ is SH, SiCl₃ or Si(OCH₃)₃.

Formula (3) is a rose bengal thiol group or a silane group.

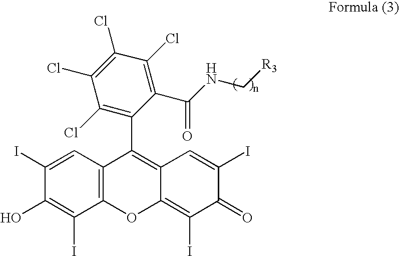

In Formula (3), R₃ is SH, SiCl₃ or Si(OCH₃)₃, and n is an integer from 2 to 20.

Formulas (4), (5) and (6) are azo compounds including an aminobenzene group having a dinitro thiophene group, and a thiol derivative or a silane derivative.

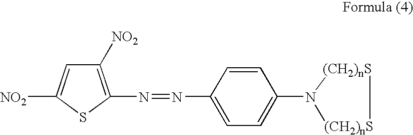

In Formula (4), n is an integer from 1 to 20.

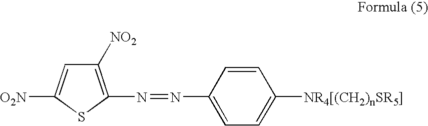

In Formula (5), R₄ is a hydrogen atom, a C₁-C₂₀alkyl or phenyl group, or (CH₂)ₙSR₅, R₅ is a hydrogen atom, an acetyl group or a methyl group, and n is an integer from 1 to 20.

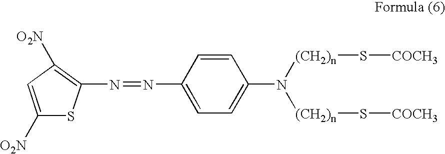

In Formula (6), n is an integer from 1 to 20.

Formula (7) is an organic metal-thiol or a silane derivative in which a terpyridyl group and a metal atom are bonded.

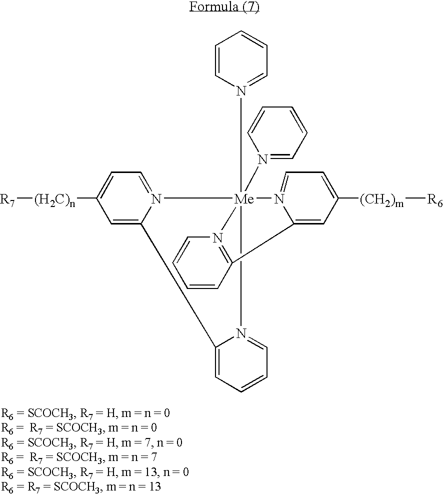

In Formula (7), Me is cobalt, nickel, iron or ruthenium.

In compounds of Formulas (1) thorough (7), a thiol derivative or a silane derivative can function as a specific functional group (alligator clip) by which the compounds can be self-assembled on the lower electrode 110 or 210. That is, with respect to the molecular electronic device 100, 200 and 300 according to an embodiment of the present invention, the molecular active layer 140 is selectively bonded on the lower electrode 110 or 210 using self-assembling methods with a thiol derivative or a silane derivative constituting an anchoring group to form a molecular layer on the lower electrode 110. The thickness of the molecular layer included in the molecular active layer 140 may be regulated by determining a length of an alkyl chain i.e. m or n of —(CH₂)ₘ— or —(CH₂)ₙ— in the compound included in the molecular layer.

The molecular electronic devices 100, 200 and 300 including the molecular active layers 140 according to the embodiments of the present invention may compose a switching element which is mutually switchable to states of ON and OFF according to voltages applied between the lower electrodes 110 or 210 and the upper metal electrodes 120 or 220. In addition, the molecular electronic devices 100, 200 and 300 including the molecular active layers 140 according to the embodiments of the present invention may compose a memory element in which a predetermined electric signal is stored according to voltages applied between the lower electrodes 110 or 210 and the upper metal electrodes 120 or 220. That is, the molecular electronic devices 100, 200 and 300 according to the embodiments of the present invention may provide memory characteristics and switching characteristics.

The organic conductive protective layers 150 included in the upper electrodes of the molecular electronic devices 100, 200 and 300 according to the embodiments of the present invention may be composed of a low molecular weight compound, an oligomer or a polymer. The organic conductive protective layers 150 may be generally bonded by conjugated double bonds by π-electrons of benzene ring, and thus electrons in the organic conductive protective layers 150 can be transported with comparative ease. Accordingly, the organic conductive protective layers 150 may provide excellent conductivity.

Examples of organic compounds of the organic conductive protective layers 150 are as follows.

First, among examples of organic compounds of the organic conductive protective layers 150, a low molecular weight compound may be various derivatives such as tetrathiafulvalene-tetracyanoquinodimethane (TTF-TCNQ), bis(ethylenedithio)tetrathiafulvalene (BEDT-TTF), etc. in which an electron donor and an electron acceptor are bound in the form of a complex. The structure of TTF-TCNQ is represented by Formula (8).

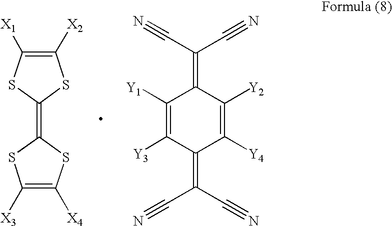

In Formula (8), X₁, X₂, X₃ and X₄ may be independently H or CH₃. Alternatively, X₁, X₂ and X₃ may be H, and X₄ may be —CH₂—SH. In addition, X₁, X₂, X₃ and X₄ may be independently —(CH₂)₈—SH. Y₁ and Y₄ may be independently H, and Y₂ and Y₃ may be H, F, Cl, Br or CH₃.

In addition, Formulas (9), (10) and (11) are structures of oligothiophene, pentacene and perylene respectively, which are organic compounds of the organic conductive protective layers 150, according to an embodiment of the present invention.

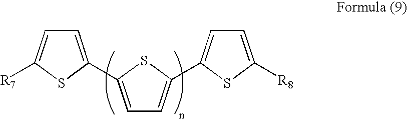

In Formula (9), R₇ and R₈ are each a hydrogen atom or a halogen atom.

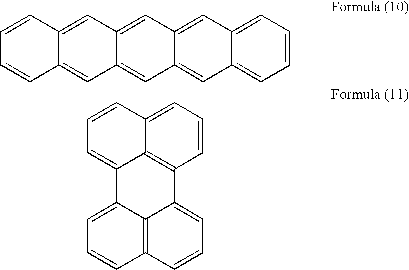

In addition, suitable polymers for forming the organic conductive protective layers 150 are polyacetylene represented by Formula (12), polyaniline emeraldine salt (PANI-ES) represented by Formula (13), polypyrrole (PPy) represented by Formula (14), polyphenylvinyl (PPV) represented by Formula (15), polyparaphenylene (PPP) represented by Formula (16), poly(vinylpyrrolidone) represented by Formula (17), poly(alkyl thiophene) represented by Formula (18), (poly(thienylenevinylene) represented by Formula (19), etc.

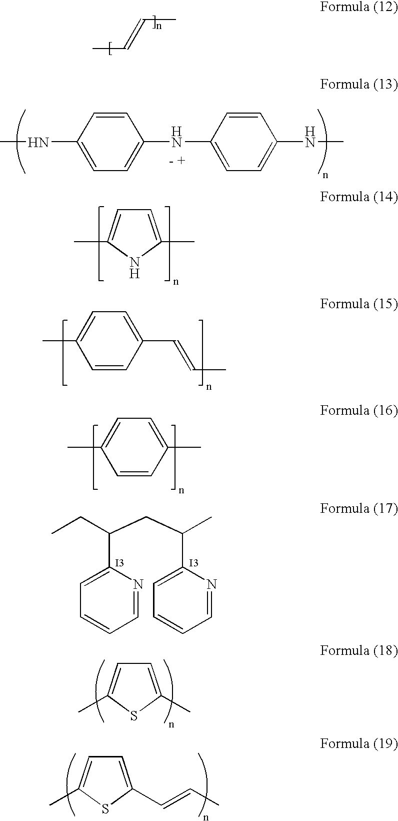

With the formation of the organic conductive protective layers 150 of the molecular electronic devices 100, 200 and 300 according to the embodiments of the present invention on the molecular active layer 140 using compounds represented by Formulas (8) thorough (19), when monomers having a low molecular weight represented by Formulas (8) thorough (11) are used, the organic conductive protective layers 150 can be formed using a vacuum deposition method using, for example, an E-beam evaporator. Here, a deposition pressure of about 10⁻⁶-10⁻⁷ Torr may be maintained and a deposition temperature of about from room temperature to 150° C. may be maintained. The organic conductive protective layers 150 may be formed by spin coating polymers represented by Formulas (12) through (19).

When the organic conductive protective layers 150 are formed, two different methods using TTF-TCNQ compounds may be performed. That is, the two different methods include a method in which each of TTF and TCNQ compounds is simultaneously deposited (co-evaporation), and a method in which TTF-TCNQ complex synthesized in solution is deposited. TTF-TCNQ compounds are deposited at a higher-degree vacuum in comparison with co-evaporation method of each of TTF and TCNQ compounds.

When polymers are used in formation of the organic conductive protective layers 150, after the polymers are dissolved in general organic solvent such as chloroform, tetrahydrofurane (THF), dimethylformamide (DMF), or an alcohol-based solvent, the resultant materials are spin coated directly on the molecular active layers 140. Here, it is necessary that an organic solvent should dissolve the organic conductive protective layer 150 well and simultaneously should be easily removed. When compounds having a silane functional group are used to form the organic conductive protective layers 150, an anhydrous solvent, for example, THF may be used. After spin coating, a used solvent may be dried, for example, in a vacuum oven in which a pressure of 10⁻⁷ Torr and a temperature of 100° C. are maintained for about 24-48 hours.

By forming the organic conductive protective layers 150, which are formed of compounds selected from Formula (8) through (19), between the molecular active layers 140 and the upper metal electrodes 120 or 220, short circuits caused by damage to or degradation of the molecular active layers 140 can be also inhibited even when ultra slim molecular electronic devices having levels of several nanometers are used, and thus a practical use of nano molecular electronic devices can be realized.

Hereinafter, a method of manufacturing a molecular electronic device according to an embodiment of the present invention will be described in greater detail.

### EXAMPLE 1

Manufacture of Molecular Electronic Device

After an insulating layer was formed on a silicon substrate, a conductive layer, on which a Ti layer having a thickness of about 5 nm and an Au layer having a thickness of about 30 nm were stacked sequentially, was formed on the resulting structure. By patterning the resulting structure, a lower electrode having a line pattern, which is similar to the lower electrodes 210 of FIG. 2A, was formed. The line width of the lower electrode was 50 nm. In order to form the lower electrode, after photoresist materials were spin coated on the insulating layer, the photoresist materials were imprinted using a stamp to form desired mask patterns. Next, Ti and Au were deposited sequentially using an e-beam evaporating method. The mask patterns were removed. Nano imprint technologies were used in Example 1, but general photolithography could be used for forming the lower electrode.

A silicon nitride film pattern having a thickness of about 60 nm and having via holes through which the lower electrode is exposed by about 120 nm width, were formed on the resulting structure on which the lower electrode was formed.

Next, an organic solvent was prepared to form the molecular active layer on the surface of the lower electrode exposed through the via hole formed in the silicon nitride film pattern. Compounds included in the molecular active layer of the molecular electronic device according to the current embodiment of the present invention were dissolved well in chloroform, dichloromethane, THF, DMF solvent, etc. The respective compounds may be dissolved in DMF solution to give a concentration of about 1-10 mmol. In Example 1, 10 ml of a solution, in which an azo compound (n=12) represented by Formula (6) is dissolved to have a concentration of 1 mmol, was prepared. Here, anoxic and anhydrous DMF solvents were used in a glove box in which anoxic and anhydrous conditions were maintained. The resulting structure, on which the lower electrode and silicon nitride film patterns were formed, was dipped for about 24 hours to form the molecular active layer which was formed to be a single molecular layer on the surface of the lower electrode exposed through the via hole using self-assembling methods. Next, the resulting structure on which the molecular active layer was formed on the surface of the lower electrode was washed using DMF, THF, ethanol and distilled water in that order. The resulting washed structure was put into a low-temperature vacuum oven (40° C., 10⁻³ Torr) and was dried for about 2 hours.

Next, pentacene represented by Formula (10) was deposited on the molecular active layer and the silicon nitride film pattern surrounding the molecular active layer so as to cover the molecular active layer using an e-beam evaporating method to form an organic conductive protective layer. Here, ten samples of the organic conductive protective layer having respective thicknesses of 10 nm, 20 nm, 30 nm, 40 nm, 50 nm, 60 nm, 70 nm, 80 nm, 90 nm and 100 nm were manufactured to evaluate effects according to the thickness of the organic conductive protective layer. An upper metal electrode was formed on the organic conductive protective layer of each sample. An upper metal electrode was formed using the same method as used to form the lower electrode except that a Ti layer having a thickness of 5 nm and an Au layer having a thickness of 65 nm were formed in a stack structure.

### EXAMPLE 2

Evaluation of Reliability of Organic Conductive Protective Layer According to Thickness

Yields were evaluated using a method of evaluating whether a short circuit was generated or not for the respective samples having different thicknesses of the organic conductive protective layer manufactured in Example 1. When the thickness of the organic conductive protective layer was 10 nm, the yield was about 30%, when the thickness of the organic conductive protective layer was 20 nm, the yield was about 50%, and when the thickness of the organic conductive protective layer was 30 nm, the yield was above 90%. On the other hand, when the thickness of the organic conductive protective layer was above 50 nm, mobility of carrier in pentacene layer was low, current flow between both electrodes was too little, and thus electrical properties were gradually removed.

From the results of the current experiment, when the organic conductive protective layer was formed of pentacene, the most optimum thickness of the organic conductive protective layer was about 30 nm.

The evaluation result in Example is only for the specific case in which specific size and materials are adopted. The evaluation result of Example 2 was not applied to every molecular electronic device according to the present invention. The optimum condition may be different according to compositions and sizes of respective elements included in the molecular electronic device according to the present invention, and other process parameters. In addition, it will be understood by those of ordinary skill in the art that various changes in form and details may be made therein without departing from the spirit and scope of the present invention.

### EXAMPLE 3

Measurement of Switching Characteristics and Memory Characteristics of Molecular Electronic Device

To measure switching characteristics and memory characteristics of the molecular electronic device (when the thickness of the organic conductive protective layer was 30 nm) manufactured in Example 1, the following experiment was operated. First, the molecular electronic device was maintained and measured in a vacuum oven in which room temperature was maintained to minimize the possibility of degradation such as oxidation of molecules, etc. Current-voltage properties were measured using a semiconductor parameter analyzer (HP 4156C, measurable from 1 fA/2V to 1 A/200V). The switching characteristics and the memory characteristics of the molecular electronic device according to the present invention were evaluated for measuring results of two directions. That is, the switching characteristics and the memory characteristics were secured from measuring results of directions from positive (+) voltage to negative (−) voltage, and from negative (−) voltage to positive (+) voltage. In addition, the switching characteristics were secured from measuring for loop from 0→(+) voltage→(−) voltage→(+) voltage.

FIG. 4 is a hysteresis graph illustrating switching characteristics for the molecular electronic device manufactured in Example 1 (when the thickness of the organic conductive protective layer was 30 nm).

From FIG. 4, it can be seen that short circuits caused by damage to a molecular active layer are prevented to obtain desired switching characteristics by using pentacene as an organic conductive protective layer. In addition, it is secured that pentacene may be used as materials of an organic electrode. Pulses required for obtaining memory characteristics are measured using a pulse generator unit (HP 41501 expander) and an SMU-PGU selector (HP 16440A) which can be connected to the above measuring apparatus.

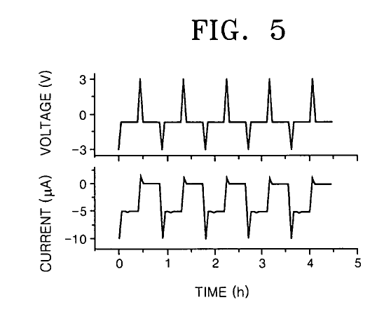

FIG. 5 is a graph illustrating memory characteristics of the molecular electronic device (when the thickness of the organic conductive protective layer was 30 nm) manufactured in Example 1.

The measuring apparatus having measuring ranges from several Hz to several MHz was set according to the switching characteristics of the molecular electronic device. In addition, rising/falling times of voltage pulses were measured so as to be within time ranges of less than 100 ns.

The molecular electronic device according to the present invention includes an organic conductive protective layer interposed between a molecular active layer self-assembled on the lower electrode and an upper metal electrode. The upper electrode of the molecular electronic device includes the organic conductive protective layer and the upper metal electrode. With respect to the molecular electronic device according to the present invention, the upper electrode includes the organic conductive protective layer i.e. an organic electrode layer, and thus a short circuit, which may be easily generated due to damage to the molecular active layer, can be effectively prevented in a molecular electronic device having a structure of lower electrode—molecular active layer—upper electrode. Accordingly, a molecular electronic device having switching characteristics and memory characteristics may be implemented and utilized with ease. In addition, with respect to the molecular electronic device according to the current embodiment of the present invention, the molecular active layer is formed to be a single molecular layer using self-assembly methods, and thus the thickness of the molecular active layer can be ultra slim in the order of several nanometers. Also, the thickness of the organic electrode layer formed on the molecular active layer is optimized, and thus a charge effect for voltages between the lower electrode and the upper metal electrode can be controlled.

As described above, to prevent the formation of short circuits due to damage to the molecular active, that is, a single molecular layer self-assembled on the metal electrode of the present invention, the organic electrode layer is formed for protecting the molecular active layer as an element of the upper electrode. Thus, a short circuit due to damage of the molecular active layer can be prevented and an ultra-slim nano-sized molecular electronic device can be implemented.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A molecular electronic device comprising:
a first electrode;
a molecular active layer self-assembled on the first electrode; and
a second electrode comprising an organic electrode layer covering the molecular active layer.

2. The molecular electronic device of claim 1, wherein the second electrode further comprises a metal electrode layer formed on the organic electrode layer.

3. The molecular electronic device of claim 1, wherein the molecular active layer comprises a compound including a thiol derivative or a silane derivative, and self-assembled to the first electrode by the thiol derivative or the silane derivative constituting an anchoring group.

4. The molecular electronic device of claim 1, wherein the molecular active layer is formed to be a single molecular layer.

5. The molecular electronic device of claim 1, wherein the molecular active layer comprises at least one selected from the group consisting of a compound comprising a nitro phenylene ethynylenethiol group, a compound comprising a nitro phenylene ethynylene silane group, a compound comprising a rose bengal thiol group, a compound comprising a rose bengal silane group, an azo compound comprising a aminobenzene group including a dinitro thiophene group and a thiol derivative, an azo compound comprising a aminobenzene group including a dinitro thiophene group and a silane derivative, an organic metal-thiol derivative comprising a terpyridyl group and a metal atom bonded on the organic metal-thiol derivative, and the organic metal-silane derivative comprising a terpyridyl group and a metal atom bonded on the organic metal-silane derivative.

6. The molecular electronic device of claim 5, wherein the metal atom is any one selected from the group consisting of cobalt, nickel, iron and ruthenium.

7. The molecular electronic device of claim 1, wherein the organic electrode layer comprises at least one selected from the group consisting of tetrathiafulvalene-tetracyanoquinodimethane (TTF-TCNQ), bis(ethylenedithio)tetrathiafulvalene (BEDT-TTF), oligo thiophene, pentacene, perylene, polyacetylene, polyaniline emeraldine salt (PANI-ES), polypyrrole (PPy), polyphenylvinyl (PPV), polyparaphenylene (PPP), poly(vinylpyrrolidone), poly(alkylthiophene), and poly(thienylenevinylene).

8. The molecular electronic device of claim 1, wherein the first electrode comprises a single metal layer formed of one metal, or a multi-layer structure comprising at least two sequentially stacked metals which are different from each other

9. The molecular electronic device of claim 2, wherein the metal electrode layer of the second electrode comprises a single metal layer formed of one metal, or a multi-layer structure comprising at least two sequentially stacked metals which are different from each other.

10. The molecular electronic device of claim 1, wherein the first electrode and the second electrode each comprise a metal layer comprising Au, Pt, Ag or Cr.

11. The molecular electronic device of claim 1, wherein a metal electrode of the second electrode has a stack structure of a barrier layer and a metal layer, and the barrier layer is formed directly on the organic electrode layer.

12. The molecular electronic device of claim 11, wherein the barrier layer comprises Ti, and the metal layer comprises Au.

13. The molecular electronic device of claim 1, wherein the molecular active layer composes a switching element which is mutually switchable to states of ON and OFF according to voltages applied between the first electrode and the second electrode.

14. The molecular electronic device of claim 1, wherein the molecular active layer composes a memory element in which a predetermined electric signal is stored according to voltages applied between the first electrode and the second electrode.
